(19) United States
(12) Patent Application Publication
(10) Pub. No.: US 2002/0148974 A1
(43) Pub. Date: Oct. 17, 2002

(54) Wafer thermal desorption system and apparatus

(76) Inventors: Chung-Kai Hung, Tai Chung (TW); Tsong-Hsueh Wu, Hsin Chu (TW); Feng-Tsair Wang, Hsin Chu (TW); Wen-Ching Wei, Taichung (TW)

Correspondence Address: RABIN & CHAMPAGNE, PC, 1101 14TH STREET, NW, SUITE 500, WASHINGTON, DC, 20005, US

(21) Appl. No.: 09/791,632

(22) Filed: Feb. 26, 2001

(51) Int. Cl. G21K 5/08; G21K 5/10; G01N 21/00; H01J 37/20; G01N 23/00

(52) U.S. Cl. 250/443.1

(57) ABSTRACT

The present invention is a kind of wafer improved thermal desorption system. Mainly, a fixed infrared heating source is supplemental attached to a heating chamber with fixed type, also, and a fixed heat reflection mask is equipped at the bottom place of the fixed heating chamber respectively. Furthermore, the invent which a contact area between heating chamber and wafer and an air detracted device supplemental attached at one terminal of carrier gas to connect with the wafer thermal desorption chamber and adsorbent tube for collecting these substances to be analyzing. Thus, the invention can adapt with different brands of thermal desorption instruments, Thermal Desorption-Gas Chromatographic-Mass Spectroscopy (TD/GC/MS), and so on, for proceeding the analysis the micro contamination on the surface of wafer.

### TECHNICAL FIELD

The invention provides a kind of improved wafer thermal desorption system and apparatus, especially which can maintain a good temperature stability during wafer's placement for having a fixed heating chamber and infrared heating source. Additionally, the apparatus can accurate measure an actual temperature for having a spring equipped on the thermocouple. Otherwise, a polished surface on the contact face between heating chamber and wafer, and the distal termination of thermal desorption chamber connects to an absorber tube and a sampling pump. The contamination on wafer's surface can be thermal desorbed, carried out and concentrated in the adsorbent tube, and then the Thermal Desorption-Gas Chromatographic-Mass Spectroscopy (TD/GC/MS)—known and often seen in the market—can be used to analyze the contamination of the adsorbent tube.

### BACKGROUND OF THE INVENTION

Normally, many procedures of processing semiconductor, such as photo, diffusion, etching and thin film, must be carried out under a high quality of cleanness circumstance. For ensuring a stability and reliability of those processes to meet the requirement of simultaneous and highly sensitive analyzing multiple substances, the wafer thermal desorption system (WTDS) and its variously related analysis equipment for pollution substances were therefore developed.

However, the analytical method of WTDS is the test sample been heated in high temperatures to de-sorb substances via carrier gas been guided into detection instruments—such as Thermal Desorption-Gas Chromatographic-Mass Spectroscopy (TD/GC/MS), Atmospheric Pressure Ionization Mass Spectrometer (APIMS) or Residue Gas Analyzer (RGA)—for the usage of detection and analysis. Of the TD/GC/MS have high sensitivity and ability to distinguish various substances, as well as APIMS and RGA only can analyze the total amount of those various substances.

Three types of thermal desorption systems (TDS) as following:

The first type shown in FIG. 2. A sample A (a wafer) cut into pieces before being placed into a tube-shaped heating chamber B. Which many of heating coils C are winding around the top of the chamber B, and a carrier gas inlet B1 and a carrier gas outlet B2 are located separately on in front and the rear of the chamber B. As nitrogen, helium or argon—high purity of carrier gas—passing through the inlet B1 and entering into the chamber B to carry polluted substances (molecules in gaseous) on the surface of test sample via outlet B2 out and into TD/GC/MS or APIMS for analyzing. Causing of this type of thermal description, which the sample A being in damaged-cutting before operation that will damage the sample A and also introduce contamination.

The second type is under a highly vacuum condition (5+10⁻¹⁰ Torr) to proceed thermal desorption, the thermal desorbent polluted-substances were been guided into RGA to be detecting and analyzing. For the operation of those substances being into the detection and analysis is in a super low pressure vacuum, which can easily cause to the external contamination getting into the thermal chamber if the sealing is not good enough, and then more contamination in the chamber will be found.

The third type is under the constant gas pressure to proceed thermal desorption via the high purified carrier gas—such as He, N₂ or Ar—to carry those various substances desorbed from the surface of test sample into the system for detecting and analyzing. Comparing the third type to the other two types of TDS, the prior appears to more accurate and reliable results in experiment and can analyze every single side of a wafer. FIG. 3 shows an atmospheric TDS designed by Hitachi where the heating chamber E—located on top of the stainless cabinet D—is made of quartz. A carrier gas inlet E1 is located on one side of the heating chamber E and the carrier gas outlet E2 on the other side. A ceramic ring F is equipped inside of the cabinet D for placing the test sample G (a wafer). A piercing hole on the bottom of the ceramic ring F to provide a thermocouple H penetrating through and reaching to the central bottom of the back of the sample for measuring sample's G actual temperature. However this type of TDS is not qualified in good air-tight, which only can adapt with APIMS to proceed analyzing but unsuitable for adapting with TD/GC/MS or RGA—known and often seen in the market—for micro-analysis.

After hard studying the defectivenesses of those conventional TDSs and repeated test improvements, this improved TDS based on many years' experiences in the field, the invention was invented for eliminating shortcomings and improving functions of others TDSs.

### SUMMARY OF THE INVENTION

This invention principle object is to provide a kind of improved thermal desorption system, which includes three keystones as following:

Firstly, the invention provides a fixed heating chamber, an infrared heating source and a heat reflection mask, which can ensure the system's stability when placing wafers on a wafer stage to improve accurate results of analysis.

Secondly, the invention comprises of a spring is set at the upper place of a thermocouple, which located on the upper of wafer's thermocouple stage. By using of spring's elasticity, the thermocouple can accurately measure actual temperatures of wafer without any measurement deviation due to vibration.

Thirdly, the invention comprises of a polished surface located at the contact face of the heating chamber and wafer, a pressure force—comes from pressing the spring and a gas extracted device—located at an absorber tube with a sampling pump to collect the substances which are required to be analyzed. Above all, which can gain more gas tight of carrier gas, can prevent contamination pollute the environment and can prevent leakage of the materials to be analyzing in the chamber.

Based on above three improvements: The invention—improved wafer thermal desorption system and apparatus—is not merely using in Atmospheric Press Ionization Mass Spectrometer (APIMS) to proceed analyzing pollution substances but adapting with Residue Gas Analyzer (RGA) and Thermal Desorption-Gas Chromatographic-Mass Spectroscopy (TD/GC/MS) for microanalysis. Especially, adapting the invention with TD/GC/MS has a high sensitivity and an ability to distinguish various substances and to reach a high level of microanalysis.

In order for the respective appraisal committee to better understand the structure, characteristics and functions of the invention, those optimal embodiments of the invention are briefly described below.

### BRIEF DESCRIPTION OF THE DRAWINGS

FIG. 1 is a cutaway view for the embodiment of the invention.

FIG. 2 is a cutaway view for the embodiment of a conventional TDS.

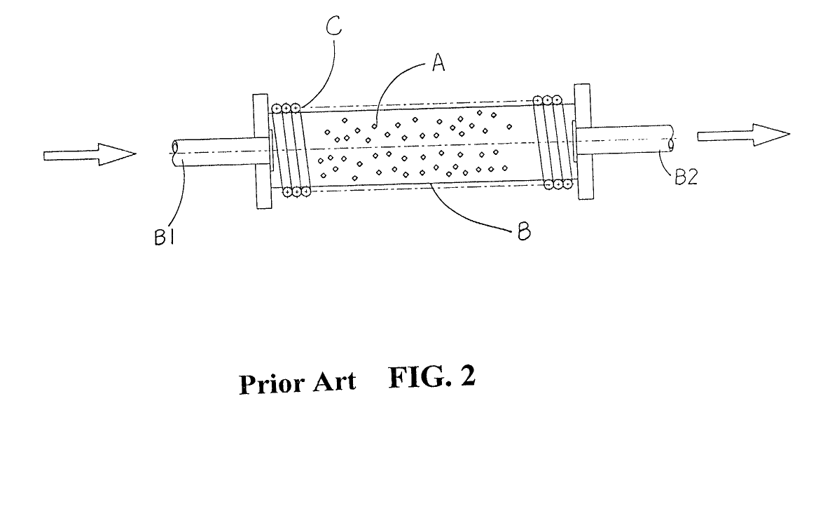

FIG. 3 is a cutaway view for the embodiment of another conventional TDS.

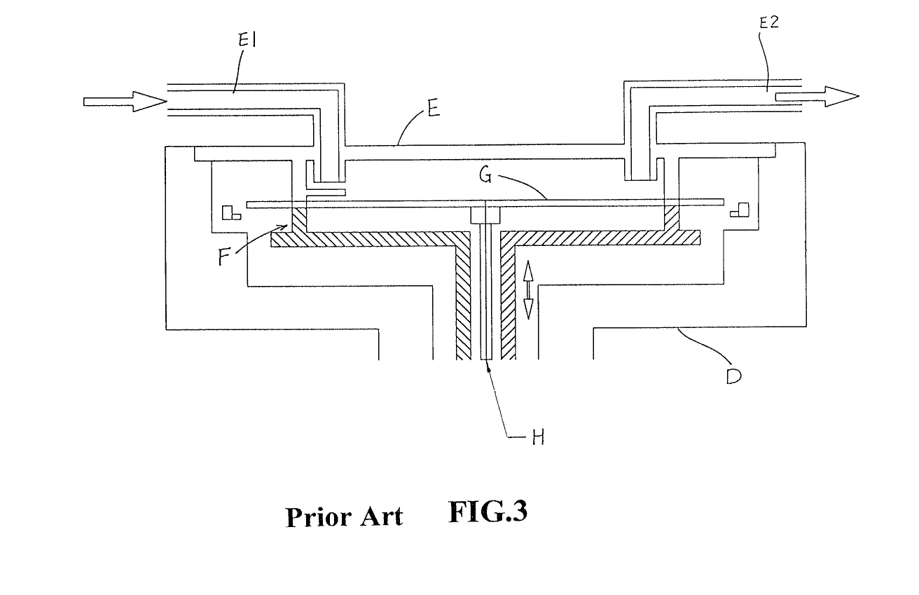

### DESCRIPTION OF TERMS

| | | | |
|---|---|---|---|
| (1) | top cabinet | (2) | bottom cabinet |
| (3) | main chamber | (4) | thermocouple Stage |
| (41) | thermocouple | (42) | spring |
| (5) | heating chamber | (51) | carrier gas inlet |
| (52) | carrier gas outlet | (6) | infrared heating source |
| (7) | heat reflection mask | (8) | wafer stage |
| (9) | wafer | (A) | test sample |
| (B) | heating chamber | (B1) | carrier gas inlet |
| (B2) | carrier gas outlet | (C) | heating coil |
| (D) | cabinet | (E) | chamber |
| (E1) | carrier gas inlet | (E2) | carrier gas outlet |
| (F) | ceramic ring | (G) | test sample |
| (H) | thermocouple | | |

### DETAILED DESCRIPTION OF THE PREFERRED EMBODIMENT

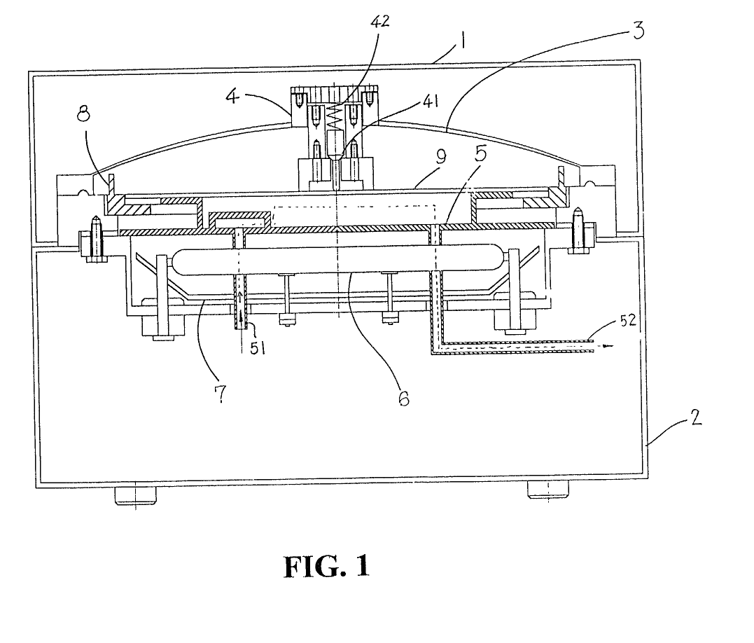

With refer to FIG. 1, the invention consists of a top cabinet (1), a bottom cabinet (2), a main chamber (3), a thermocouple Stage (4), a heating chamber (5), an infrared heating source (6), a heat reflection mask (7), a wafer table (8) and a wafer (9). The top cabinet (1) and bottom cabinet (2) are made of stainless steel and connected together as a whole by bolts. The main chamber (3) is also made of stainless steel where its top section is in arc shape and its middle section is connected with a thermocouple stage (4). A spring (42) is equipped on thermocouple (41) inside thermocouple stage (4) to push against and lock to thermocouple (41), so that the thermocouple (41) can accurately measure an actual temperature without any measurement deviation caused by vibrations.

The heating chamber (5) is made of quartz where its outer rim equipped with wafer stage (8) for placing wafer (9). A contact face of heating chamber and wafer had been polished to reach a high level of flatness on its surface. A contacted-type thermocouple (41) is located at the upper place of wafer (9), the wafer can be heated up in heating chamber (5) where an infrared heating source (6) located at the bottom of the chamber (5). A heat mask (7) is equipped at the back of infrared heating source (6), and the source (6) comprising many sets of infra red (IR) lamps. A carrier gas inlet (51) is located on one upper side of Heating Chamber (5) and the other downside is a carrier gas outlet (52). For the heating chamber (5) is made of quartz, which can decrease the adsorption—generated from the desorbed substances being attached at the chamber (5)—and can increase an accurate result in analysis. Additionally, with high penetrative characteristics of quartz, the heats from infrared heating source (6) can reach sample (9) (wafer's surface) efficiently and to reach a required temperature promptly and precisely.

Furthermore, a temperature measured from the thermocouple (41), the powers generated from infrared heating source (6) and a PID temperature controller, which shall form a feedback controlling loop to control the temperature of the test sample (9) (wafer's surface) more precisely as preset ones. Thus, the contamination on the sample' (9) surface will be vaporized under the preset temperature, and carried out by the carrier gas—such as nitrogen, helium or argon—which is from the carrier gas inlet (51). The contamination will be delivered to the carrier gas outlet (52) and APIMS for detection. For using in TD/GC/MS as a detection apparatus, the carrier gas outlet (52) can connect with an adsorbent tube and a sampling pump. After thermal desorption, the adsorbent tube can be analyzed by TD/GC/MS.

In summary, the heating chamber (5), infrared heating source (6) and heat reflection mask (7) of the invention-improved wafer thermal desorption system and apparatus—are designed in a fixed type, which provides a good stability for placing wafer (9) during operations. For a spring (42) equipped on the upper side of thermocouple (41) can allow thermocouple (41) to accurate measure an actual temperature without any measurement deviation caused by vibrations. Otherwise, a polished surface located on the contact face between heating chamber and wafer, and the distal termination of thermal desorption chamber connects to a sampling pump with an adsorbent tube. The contamination can be adsorbent tube and can be analyzed by Thermal Desorption-Gas Chromatographic-Mass Spectroscopy (TD/GC/MS). While a practicability of the present invention is apparent and a fact that the invention has never been made neither public nor published on any document before. So, the invention certainly meets all requirements of Patent Laws as well as this application is therefore presented in accordance with the related regulations.

What is claimed is:

1. The invention is a kind of improved wafer thermal description system and apparatus, which consisting of a top cabinet, a bottom cabinet, a main chamber, a thermocouple stage, a heating chamber, an infrared heating source, a wafer stage and a wafer, herein
The top cabinet and bottom cabinets are bolted together as a whole, and the thermocouple stage is located inside the main chamber, those specialties of the invention are described as following:
Both of infrared heating source and heat reflection mask are designed in a fixed type, which are equipped at upper and bottom place of the heating chamber separately, and
A wafer stage is equipped on the outer rim of the heating chamber for placing a wafer and the wafer can be heating up inside the heating chamber, and
A polished surface with highly smooth and plane is located on the contact area of heating chamber and wafer, and
A thermocouple is equipped inside the thermocouple stage to touch and contact with the wafer, and
A spring is installed at the upper place of thermocouple for the thermocouple can accurate measure an actual temperature without any measurement deviation caused by the system's vibration, herein, pushing and pressing on the spring to reach a high quality of air tight between the camber and wafer.

2. According to claim 1, the heating chamber is made of quartz.

3. According to claim 1, the carrier gas outlet can be supplementary attached with an adsorbent tube and air detracted device.

4. According to claim 1, the carrier gas inlet and carrier gas outlet are located at different terminals of the heating chamber' bottom place.
